(19) United States
(12) Patent Application Publication
(10) Pub. No.: US 2007/0200137 A1
(43) Pub. Date: Aug. 30, 2007

(54) Dilithium crystal trigger module - solid state

(76) Inventor: Bret William Smith, Richfield, MN (US)

Correspondence Address: Bret W. Smith, 6625 3rd St S, P.O. Box 23465, Richfield, MN, 55423, US

(21) Appl. No.: 11/360,281

(22) Filed: Feb. 24, 2006

(51) Int. Cl. H01L 45/00

(52) U.S. Cl. 257/108

(57) ABSTRACT

The acquisition of seismic data is increasingly more important in today's modern world. There are many forms of seismic data. Seismic data records are acquired and analyzed for applications ranging from subsurface engineering, environmental and/or water exploration, to deep oil-gas applications. It is very important to understand that for the acquisition of this seismic data “signal-stacking” is a crucial part of the data acquisition process. This allows the data to be “stacked”, the seismic signals are mathematically summed, in order to eliminate unwanted noise from the data such as wind energy, airplanes . . . etc. A precise, reliable and durable triggering mechanism capable of enduring heavy repeatable shock's had to be developed in order to facilitate this requirement. There have been many attempts to create the ideal triggering device or apparatus, but until now, not one was inexpensive and not one proved to be durable, reliable & precise.

### FIELD OF THE INVENTION

This invention relates to precise triggering for time zero applications for all modern solid state seismic recording systems or other solid state DC voltage devices which require precise reliable, triggering, using specific G force trigger coefficients. In one aspect, the invention relates to the reliability and durability of the triggering and the accuracy or repeatability of the trigger point in time. In another aspect, the invention also relates to the triggering of any device using a specified G force( variable sensitivity), applied to the trigger module in any incidence or all incidences and directions (omni-directional). The use of this unique Dilithium compound has been synthesized and incorporated into the apparatus to greatly enhance this new triggering capability. Note, the design of the apparatus does not need the Dilithium compound to work. The unique compound Dilithium was developed to enhance the overall performance of the apparatus. This design is totally unique and yet very simple.

### BACKGROUND OF THE INVENTION

Historically, it has been very difficult and expensive to produce a seismic triggering apparatus which is designed to last long and prove to be very reliable in the field in conjunction with a wide variety of seismic sources. This is primarily because of the intensity of the repeated shock waves which these trigger apparatuses' have to be designed to sustain in the field, are so great on each impact, that they tend to fracture and break the internal components of the other current modern trigger switch modules relatively quickly in the field. The collection of seismic data productively, in-expensively and expeditiously in the field is a serious requirement for today's seismic oil and gas exploration industry as well as environmental or other seismic applications. Especially with state of the art-modern accelerated mechanical impacting seismic sources. Many other modern current trigger switch models, all of which are solid state, none of which are patented, break consistently from use in the field and have proven to be un-reliable in the field for time zero switching, despite their great expense. The development of this new module design accompanied by the development of the “Dilithium ” compound changes this field performance dramatically. Tens of thousands of impacts have been sustained by this new design, even without the Dilithium compound added into the soldered mass, the apparatus works very well. When I add the Dilithium compound to the soldered mass, I tested it's performance and found it to even greater enhance the overall performance of the trigger modules (solid-state), triggering capability both for reliably and repeatable results in the field. Literally, thousands of repeatable and reliable impacts have been sustained by this new design, producing reliable and repeatable trigger switch closings. Just a few years ago this was un-heard of for any solid state triggering device known to mankind! I greatly hope I can obtain a patent to protect my invention and it's design, as customers are now cutting my modules open and looking at the design after they work so well for them.

### SUMMARY OF THE INVENTION

The simple design, evolved from years of experience in the field with such apparatuses and a new design of the module's interior and also compound which I refer to as “Dilithium”. The development of this compound was researched by myself and no one else and is a combination chemicals that I synthesized together using pre-existing chemical compounds. The unique inner shape and design which has been developed and which should be the heart of the Patent was also thoroughly developed and researched by myself exclusively. This simple design includes: A soldered tinned inner copper wire which holds a soldered mass(a specifically positioned mass of solder (can be in crystalform)), at a specific point along the tinned copper inner wire inside a conductive copper sealed tube within the outer Aluminum or Titanium hull, which can be of any size. The location of this point of massed solder and the size or total mass of the soldered mass, will determine the specific sensitivity of the trigger(sensitivity is set at time of manufacturer). The Dilithium compound is added to the soldered mass as part of the solder itself when it is a very hot liquid and as it cools it crystallizes within the soldered mass forming what I call the “Dilithium Crystal”. Then, it is also added as a liquid coating to this soldered mass after it has cooled to room ambient temperature. This is a totally unique apparatus design (shape) and I could not find any such design covered under any current Patent. The chemical equation for the Dilithium I use is as follows: C₁₃H₉N₅O₉S₂Li₂. Note, the Li₂ this is Lithium 2, hence my name Dilithium. In this state, it is a powder at room temperature and pressure. A very conductive powdered. This, powder is added to the soldered mass when hot and forms what I call the Dilithium-Crystal as the solder cools. This is really just part of the heart of this design, which is really the shape and design itself. Note, the Dilithium compound can be added to the soldered mass as it cools and also as a liquid coating to the crystal and inner coil mounting wire, which will greatly enhance it's performance. But the addition of this compound is not necessary for the trigger to operate very successfully. The overall shape and design is what is totally unique and should actually be the heart of this patent!

### BRIEF DESCRIPTION OF THE DRAWINGS

FIG. 1 illustrates the side view entire module or side view “cut-away” cross section view of my Dilithium Crystal Trigger Module Sold State.

FIG. 2 illustrates the side view of the inner crystal coil or copper tube, with a “cut-away” cross section of my Dilithium Crystal as it can be situated.

FIG. 3 illustrates the side view of the inner Dilithium Crystal. Note the mass of this crystal can be variable as well as it's placement along it's mounting wire.

FIG. 4 illustrates a 45 degree angle view close up of the inner Dilithium Crystal as it would appear in a formed crystal mass with solder in an Orthorhomic-Disphenoidal crystal shape. The mass of this crystal can be variable as well as it's placement along it's mounting wire.

FIG. 5 illustrates a perpendicular side close up view of the inner Dilithium Crystal as it would appear in a formed crystal mass with solder in an Orthorhomic-Disphenoidal crystal shape. The mass of this crystal can be variable as well as it's placement along it's mounting wire

FIG. 6 shows a picture of one of my standard triggers with a ruler placed next to it to give it scale.

FIG. 7 shows a picture of where the trigger is typically mounted on a signal stacking mechanical seismic source.

### DETAILED DESCRIPTION OF THE DRAWINGS

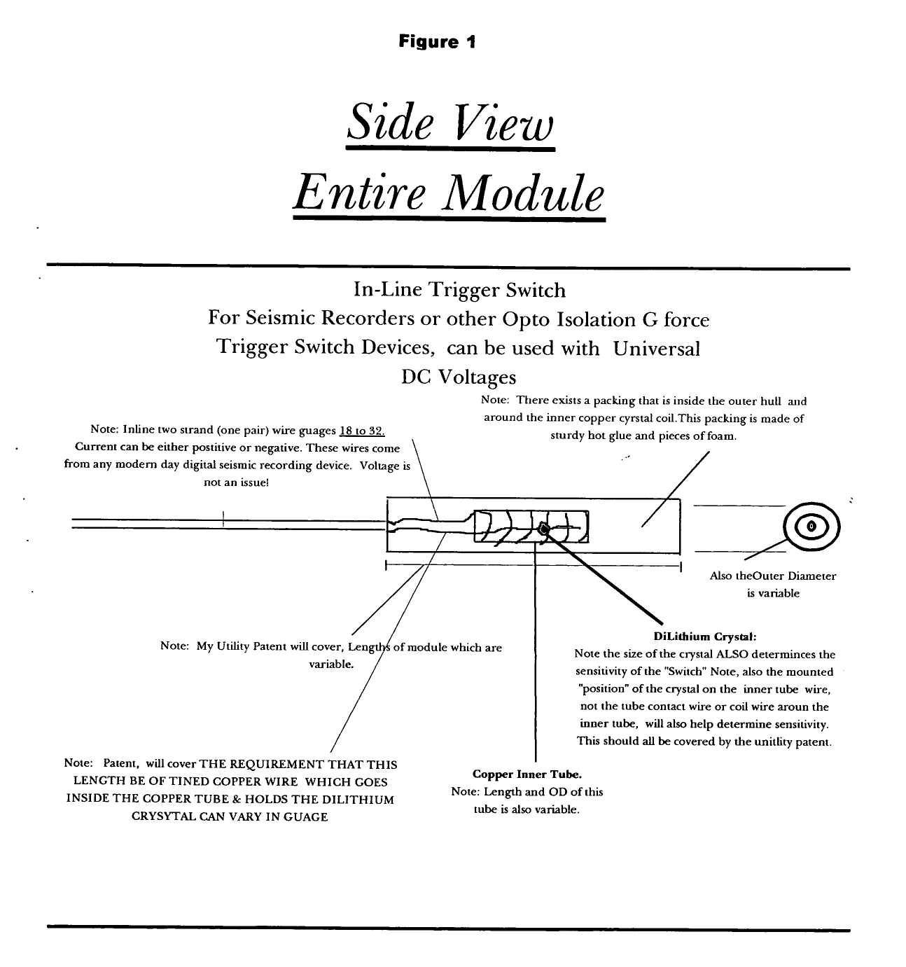

FIG. 1: Illustrates the side view entire module or side view. This is cut away so the position and relative size of the Dilithium crystal can be seen. Note that the size of this crystal and the mounting position of the crystal on the wire will affect the “sensitivity” of the trigger. The wires coming into the crystal are the “Switch” wires for the seismic recorder. There are only two and the amount of DC voltage does not matter. There is significant packing or padding around the inner copper crystal coil and inside the outer hull. This hull can be made from a variety of metals. I currently use Aluminum.

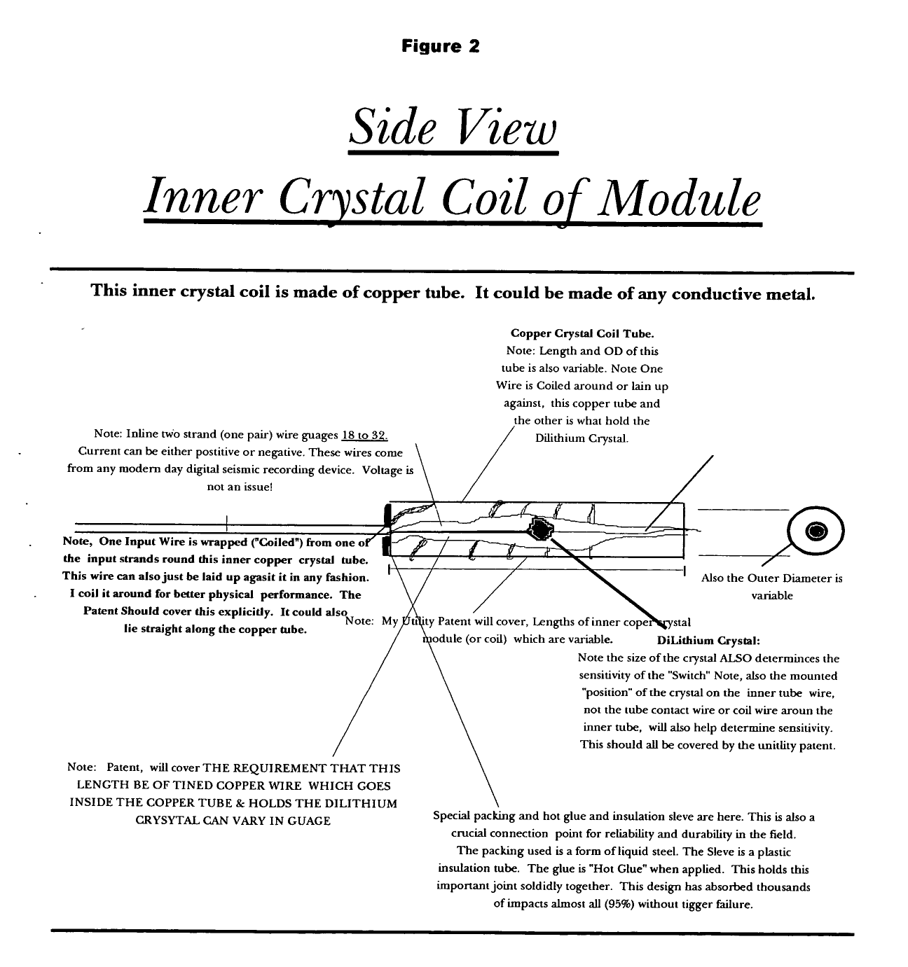

FIG. 2: Illustrates the side view of the inner copper crystal coil This view shows a cut away portion of the crystal coil to so the position and relative size of the Dilithium crystal can be seen. Note that the size of this crystal and the mounting position of the crystal on the mounting wire will affect the “sensitivity” of the trigger. One of the input wires is wrapped around this clean copper coil. I call it the crystal coil. The other wire is the crystal mounting wire that goes inside the copper crystal coil. I use copper here for the crystal coil, but any conductive metal tube will work with this design.

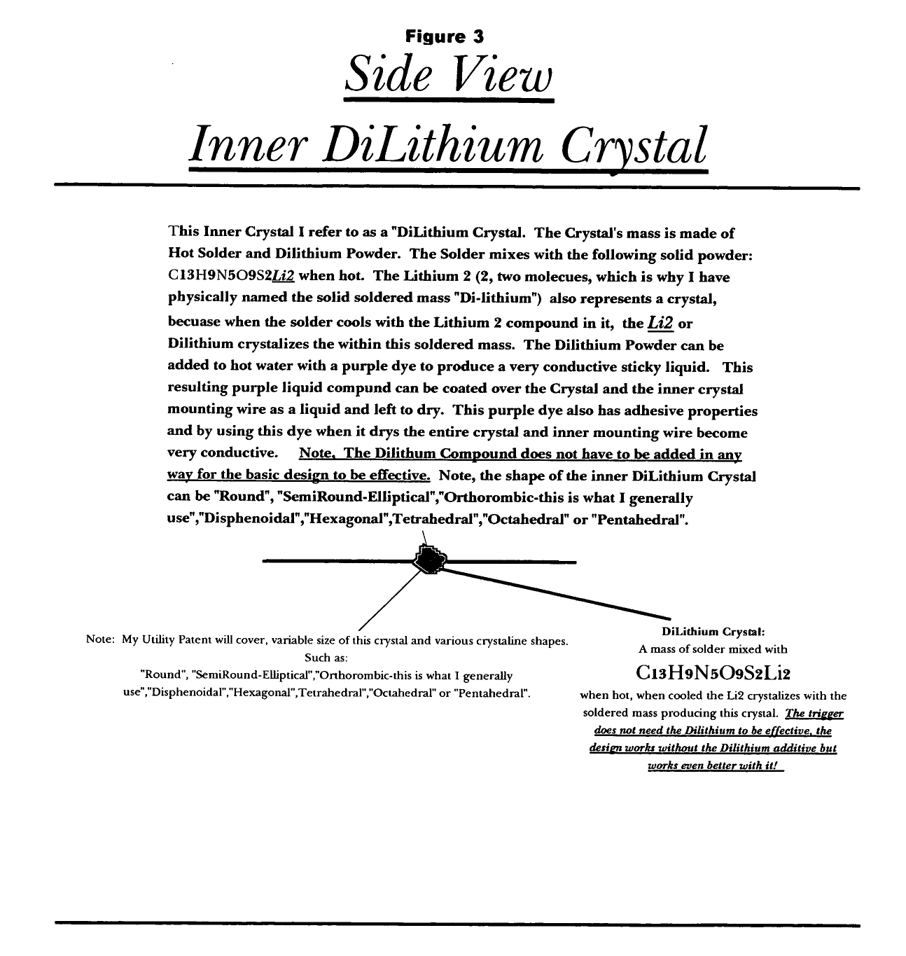

FIG. 3: Illustrates the side view entire module or side view. This is cut away so the position and relative size of the Dilithium crystal can be seen. Note that the size of this crystal and the mounting position of the crystal on the wire will affect the “sensitivity” of the trigger. The incorporation of the powdered Dilithium compound into the hot solder during the manufacture of the soldered mass crystal, and the coating over the soldered mass crystal and inner coil mounting wire as a liquid, is not necessary to have a functioning trigger. But this is the standard procedure for building and sending my product to the clients. The schematics below show the standard shape of the crystalline soldered mass. This shape is the most productive and efficient shape for the crystalline soldered mass, but the shape can also be any Circular mass, Octahedral mass or Tetrahedral mass. The hot solder does not have to be combined with the Dilithium compound for this design to work. For standard practice we use an Orthorhomic-Disphenoidal shape to the soldered mass because of years of testing and analysis of the results, this shape has proven to be the most stable and reliable. Schematic 1, 2 below shows a close up and detailed descriptions for the shape of the crystal that is I use as a standard practice. Note, the size of the mass, relative the size of the inner copper crystal tube will effect the sensitivity of the trigger.

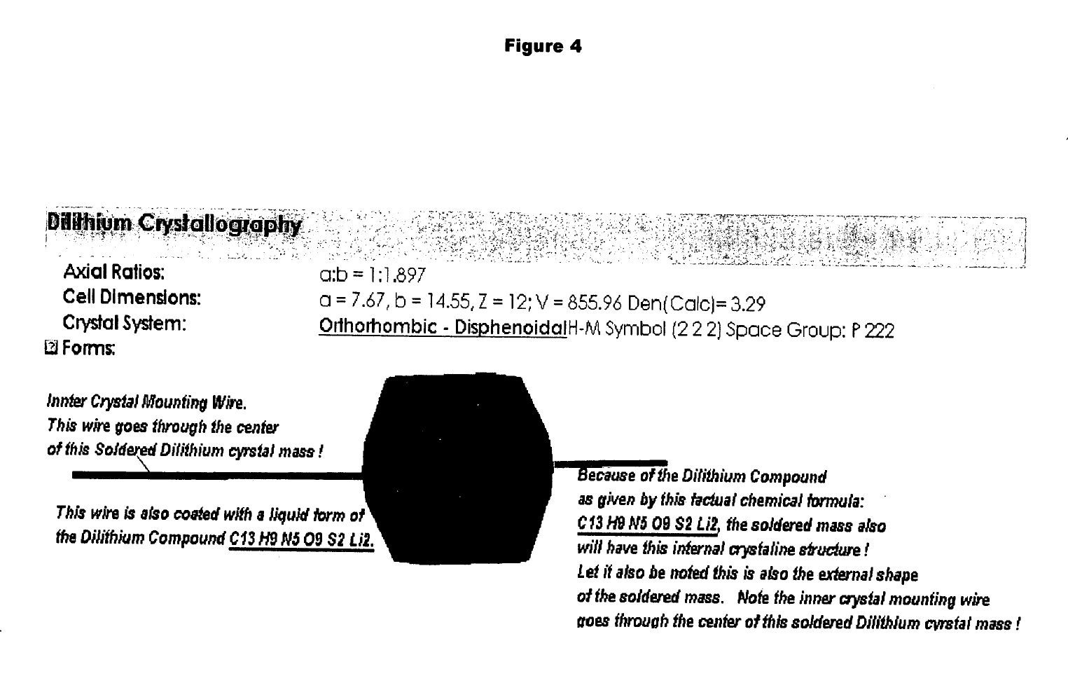

FIG. 4: This figure shows the typical crystal form that I use the most in an approximately 45 degree angle close up view. I use an Orthorhomic-Disphenoidal shape to the soldered mass because this shape produces the most accurate trigger in all or omni directions. I have found this crystal shape after years of testing the product and analysis of the results from the seismic signals. This shape has definitely proven to be the most stable and reliable. But other crystal shapes can be used. It is important to note here that the Dilithium crystal is very conductive. More so than gold or silver. Because of this a very accurate reliable and precise trigger, time zero event is produced.

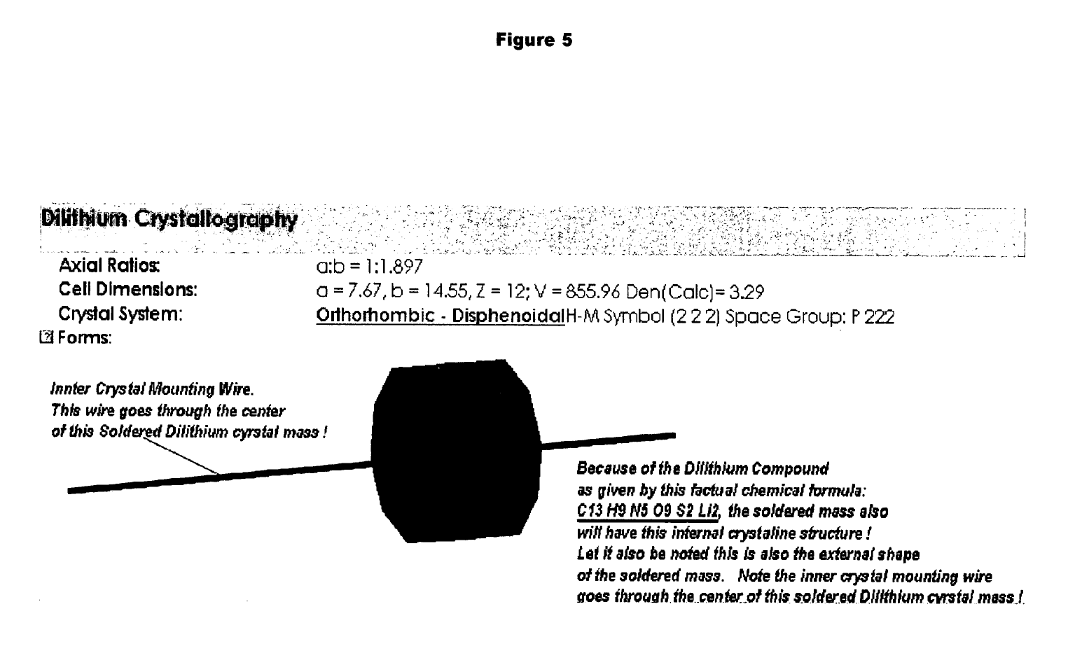

FIG. 5: This figure shows the typical crystal form that I utilize the most in my triggers. A complete side view close up, 90 degrees from the side. Please again note the Orthorhomic-Disphenoidal shape to the soldered crystal mass. This crystal shape has found to produce the most accurate trigger also in all or omni directions (impacts from all sides top and bottom).

FIG. 6: This figure shows a picture of a standard trigger of mine with a ruler by it. The basic shape and it's design is unique. The actual size can be variable and so can the color.

FIG. 7: This figure shows a picture of a standard trigger mounted to a typical impact-plate of a typical shallow (100 lb hammer) signal stacking seismic source.

1. A solid state seismic trigger apparatus comprising a Dilithium crystal, geometrically situated in a inner copper tube which is intern situated inside an aluminum (outer hull) tube.

2. A solid state seismic trigger apparatus that works with universal DC voltages.

3. A solid state seismic trigger apparatus that will “switch”,“trigger” in true omni or all directions.

4. A solid state seismic trigger apparatus that can be made with variable sensitivity G force triggering, as a function of the mass or size of the Dilithium crystal and or the size of the copper tube and/or aluminum tube, housing the copper crystal coil and the Dilithium crystal itself.

5. In line trigger switch for ALL seismic recorders, and/or other opto-isolation G force trigger switch apparatuses, with universal DC voltages.

6. A solid state seismic trigger apparatus comprising a soldered mass in crystal form, geometrically situated in a inner copper tube which is intern situated inside an aluminum (outer hull) tube. The mass of solder may or may not contain a Dilithium compound additive.
